(19) United States
(12) Patent Application Publication
(10) Pub. No.: US 2026/0053006 A1
(43) Pub. Date: Feb. 19, 2026

(54) SEMICONDUCTOR DEVICE

(71) Applicant: Rohm Co., Ltd., Kyoto-shi (JP)

(72) Inventors: Yosui FUTAMURA, Kyoto-shi (JP); Ryuta KIMURA, Kyoto-shi (JP)

(21) Appl. No.: 19/297,568

(22) Filed: Aug. 12, 2025

(30) Foreign Application Priority Data
Aug. 19, 2024 (JP) 2024-137554

(51) Int. Cl. H01L 23/495; H01L 23/00; H01L 23/31

(52) U.S. Cl. CPC H01L 23/49513; H01L 23/3114; H01L 23/49562; H01L 23/562; H01L 24/32; H01L 24/48; H01L 24/73; H01L 2224/32245; H01L 2224/48175; H01L 2224/73265; H01L 2924/13091; H01L 2924/3512; H01L 2924/35121

(57) ABSTRACT

A semiconductor device includes a support including a base member having a first main surface facing a thickness direction, a semiconductor element, and a bonding material that bonds the support and the semiconductor element. The bonding material includes a sintered metal portion and a resin portion. The support includes a metal layer located on the first main surface and having a stronger sintered bonding with the sintered metal portion than the base member. The bonding material includes a first portion in contact with the semiconductor element and the metal layer, and a second portion in contact with the semiconductor element and the base member.

### FIELD

The present disclosure relates to a semiconductor device.

### BACKGROUND

JP-A-2024-027893 discloses an example of a conventional semiconductor device. The semiconductor device disclosed in the document includes a lead and a semiconductor element.

The semiconductor element is bonded to the lead by a sintered bonding.

### DRAWINGS

FIG. 1 is a perspective view showing a semiconductor device according to a first embodiment of the present disclosure.

FIG. 2 is a perspective view showing the semiconductor device according to the first embodiment of the present disclosure.

FIG. 3 is a partial plan view showing the semiconductor device according to the first embodiment of the present disclosure.

FIG. 4 is a partial plan view showing the semiconductor device according to the first embodiment of the present disclosure.

FIG. 5 is a bottom view showing the semiconductor device according to the first embodiment of the present disclosure.

FIG. 6 is a cross-sectional view taken along line VI-VI in FIG. 3.

FIG. 7 is a cross-sectional view taken along line VII-VII in FIG. 3.

FIG. 8 is a partial cross-sectional view showing the semiconductor device according to the first embodiment of the present disclosure.

FIG. 9 is a partially enlarged cross-sectional view showing the semiconductor device according to the first embodiment of the present disclosure.

FIG. 10 is a partial plan view showing a semiconductor device according to a first variation of the first embodiment of the present disclosure.

FIG. 11 is a partial plan view showing a semiconductor device according to a second variation of the first embodiment of the present disclosure.

FIG. 12 is a partial plan view showing a semiconductor device according to a third variation of the first embodiment of the present disclosure.

FIG. 13 is a partial plan view showing a semiconductor device according to a fourth variation of the first embodiment of the present disclosure.

FIG. 14 is a partial plan view showing a semiconductor device according to a fifth variation of the first embodiment of the present disclosure.

FIG. 15 is a partial plan view showing a semiconductor device according to a second embodiment of the present application.

FIG. 16 is a partial plan view showing a semiconductor device according to a first variation of the second embodiment of the present disclosure.

FIG. 17 is a partial plan view showing a semiconductor device according to a second variation of the second embodiment of the present disclosure.

FIG. 18 is a partial plan view showing a semiconductor device according to a third embodiment of the present application.

FIG. 19 is a partial cross-sectional view showing a semiconductor device according to a fourth embodiment of the present application.

### EMBODIMENTS

The following describes preferred embodiments of the present disclosure in detail with reference to the drawings.

The terms such as “first”, “second” and “third” in the present disclosure are used merely as labels, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a part of an object B”. Further, the phrase “a plane A faces (a first side or a second side) in a direction B” in the present disclosure is not limited to the case where the angle of the plane A with respect to the direction B is 90°, but also includes the case where the plane A is inclined to the direction B.

### First Embodiment

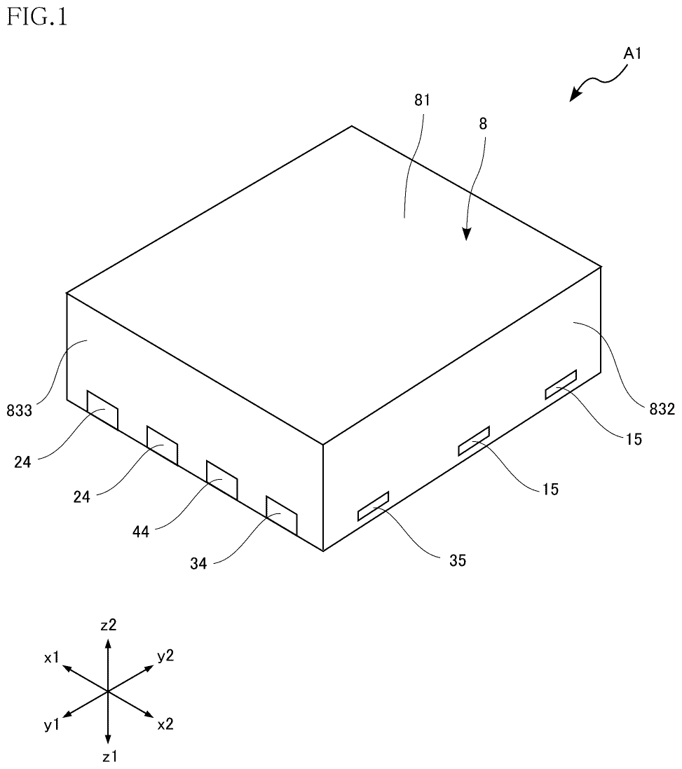

A semiconductor device A1 according to a first embodiment of the present disclosure will be described based on FIGS. 1 to 9. The semiconductor device A1 may include a support 1, a bonding material 5, and a semiconductor element 6, a lead 2, a lead 3, a lead 4, wires 71 to 73, and a scaling resin 8.

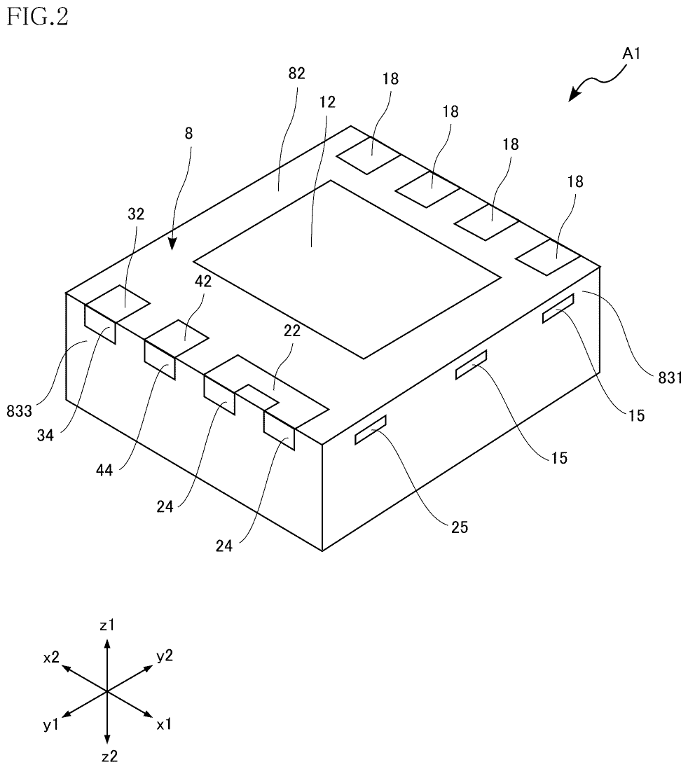

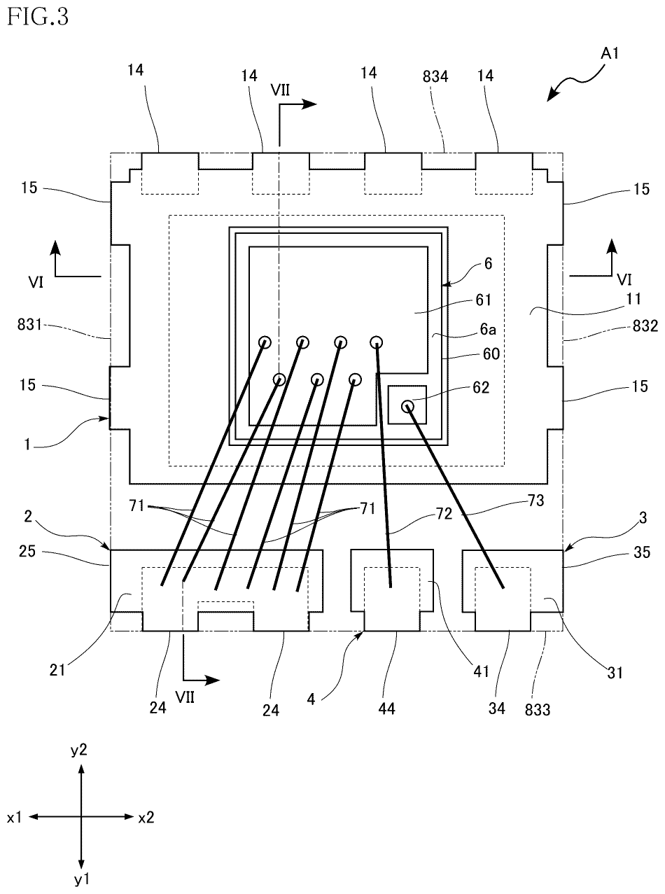

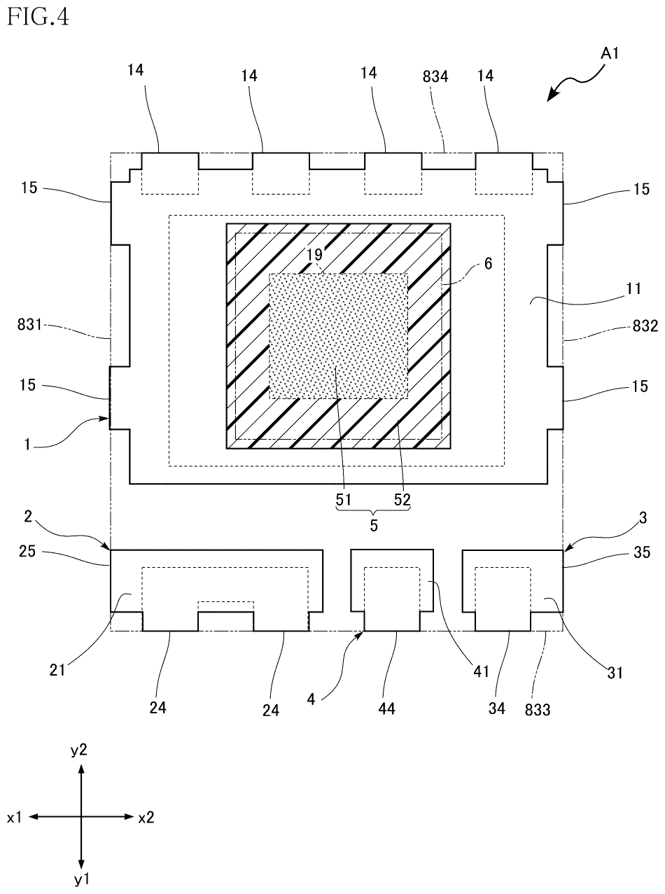

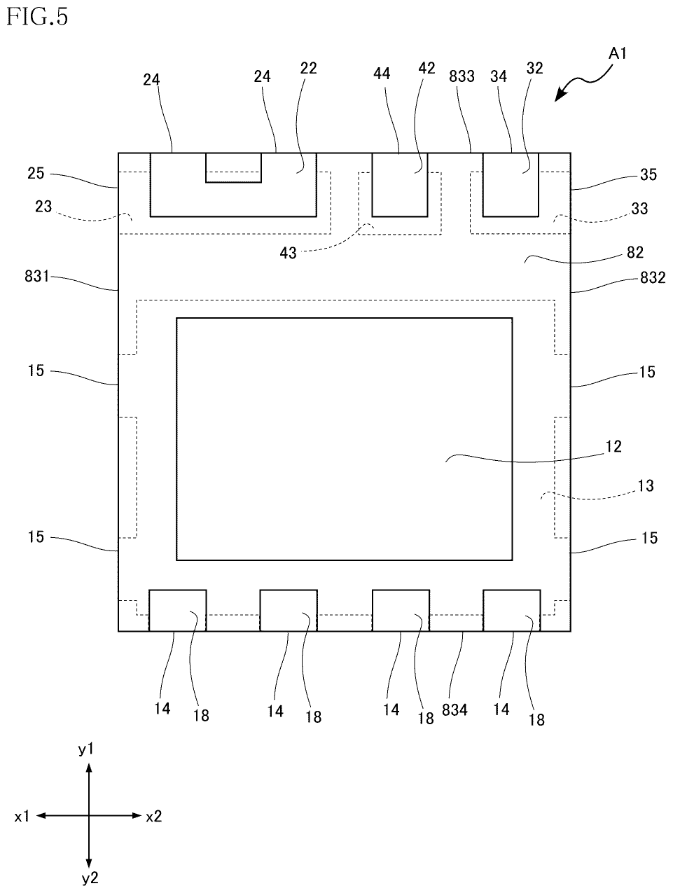

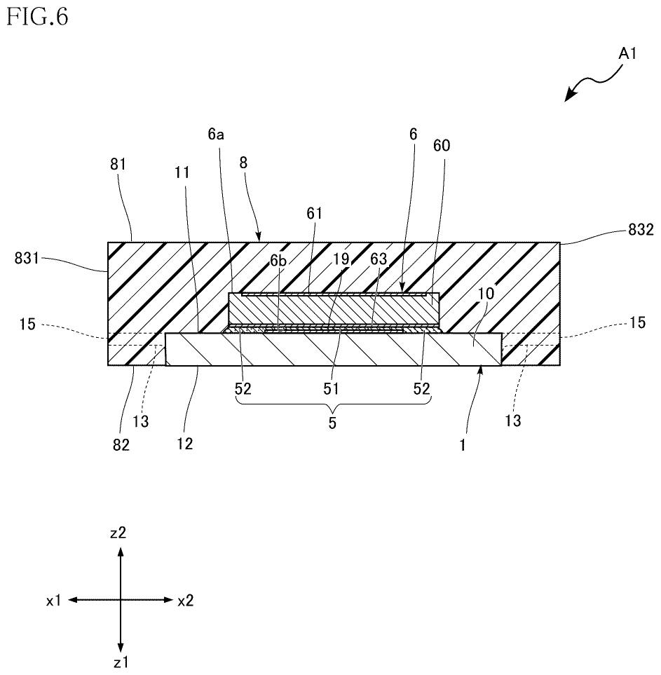

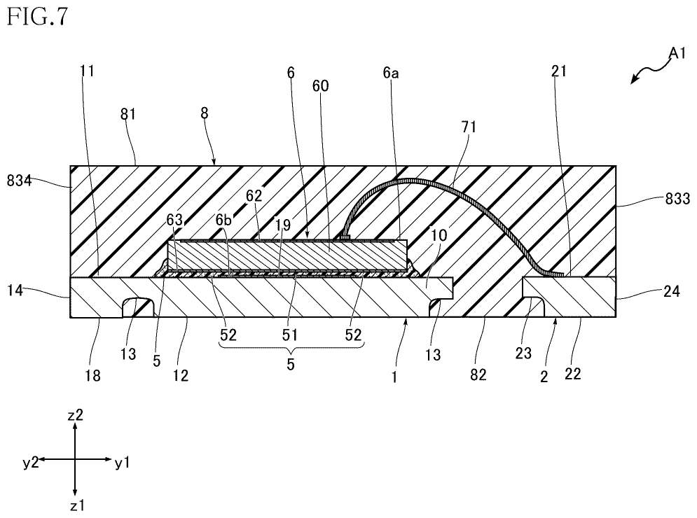

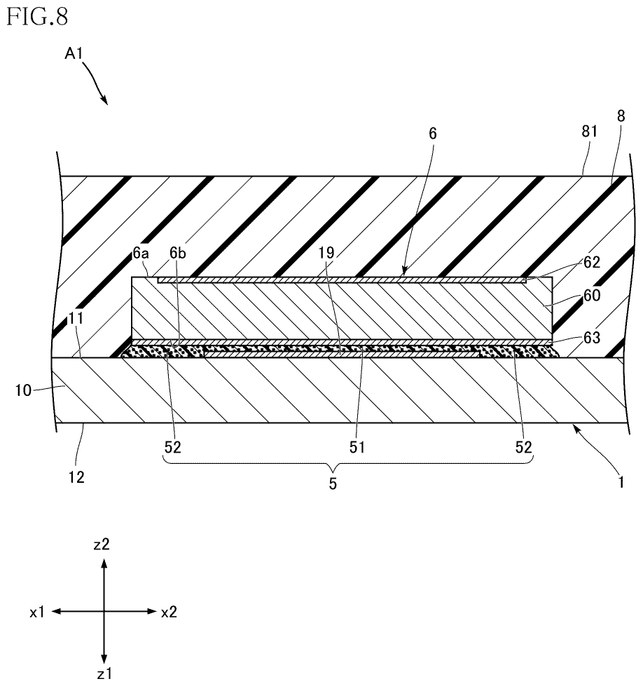

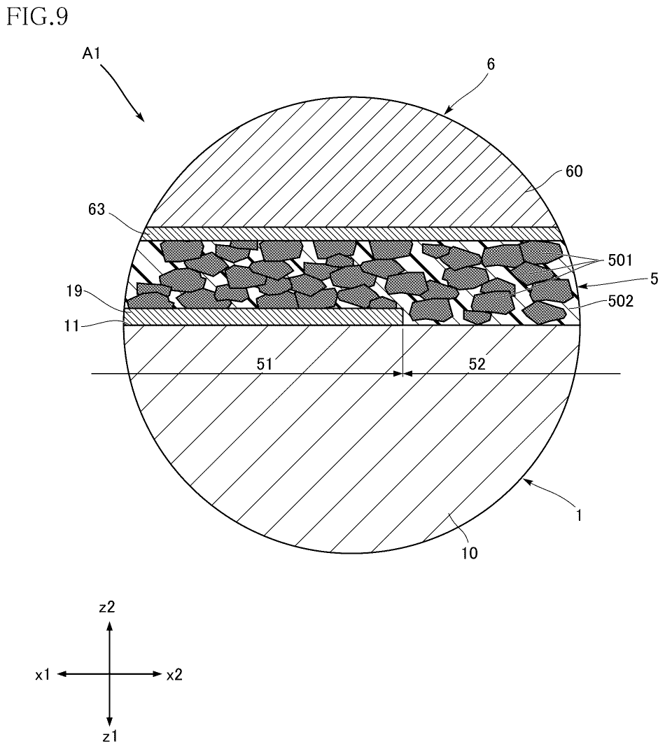

FIG. 1 is a perspective view showing the semiconductor device A1. FIG. 2 is a perspective view showing the semiconductor device A1. FIG. 3 is a partial plan view showing the semiconductor device A1. FIG. 4 is a front view showing the semiconductor device A1. FIG. 5 is a bottom view showing the semiconductor device A1. FIG. 6 is a cross-sectional view taken along line VI-VI in FIG. 3. FIG. 7 is a cross-sectional view taken along line VII-VII in FIG. 3. FIG. 8 is a partial cross-sectional view showing the semiconductor device A1. FIG. 9 is a partially enlarged cross-sectional view showing the semiconductor device A1. In FIGS. 2 and 3, the sealing resin 8 is indicated by an imaginary line (double-dotted line).

The semiconductor device A1 may be a surface mounted device on a circuit board of various types of equipment. The application and function of the semiconductor device A1 are not limited. The package type of the semiconductor device A1 may be DFN (Dual Flatpack No-leaded). The package type of the semiconductor device A1 is not limited to DFN. The semiconductor device A1 has a rectangular shape as viewed in the thickness direction. For convenience of explanation, the thickness direction (plan view direction) of the semiconductor device A1 is referred to as a thickness direction z, one direction (horizontal direction in FIG. 3) along one side of the semiconductor device A1, which is orthogonal to the thickness direction z, is referred to as a first direction x, and the direction orthogonal to the thickness direction z and the first direction x (vertical direction in FIG. 3) is referred to as a second direction y. One side of the thickness direction z (lower side in FIGS. 6 and 7) is referred to as a first side z1, and another side (upper side in FIGS. 6 and 7) is referred to as a second side z2. One side of the first direction x (left side in FIGS. 3 and 5) is referred to as a first side x1, and another side (right side in FIGS. 3 and 5) is referred to as a second side x2. One side of the second direction y (lower side in FIGS. 6 and 7) is referred to as a first side y1, and another side (upper side in FIGS. 6 and 7) is referred to as a second side y2. Each dimension of the semiconductor device A1 is not limited, and in the present embodiment, may be about 8 mm in the first direction x, about 8 mm in the second direction y, and about 1 mm in the thickness direction z, for example.

The support 1 supports the semiconductor element 6. The support 1 may be electrically connected to or electrically isolated from the semiconductor element 6. The leads 2, 3 and 4 are electrically connected to the semiconductor element 6. The support 1 and the leads 2, 3 and 4 may be formed, for example, by subjecting a metal plate to etching or punching. The support 1 and the leads 2, 3 and 4 contain metal, and preferably contain Cu, Ni, or alloys thereof, or 42 Alloy.

In the present embodiment, a case where the support 1 and the leads 2, 3 and 4 contain Cu is explained as an example. The thickness of each of the support 1 and the leads 2, 3 and 4 is not particularly limited, and may be between 0.08 mm and 0.3 mm, for example, and in the present embodiment may be about 0.2 mm.

As shown in FIG. 3, the support 1 is located at an end on the second side y2 in the second direction y of the semiconductor device A1, and extends across the entire range in the first direction x. The leads 2, 3, and 4 are located at an end on the first side y1 of the second direction y of the semiconductor device A1, each spaced apart from the support 1 and arranged side-by-side in the first direction x with gaps between them. The lead 2 is disposed at the corner on the first side x1 in the first direction x and the first side y1 in the second direction y (lower-left corner in FIG. 3) of the semiconductor device A1. The lead 3 is disposed on the second side x2 in the first direction x and the first side y1 in the second direction y (lower-right corner in FIG. 3) of the semiconductor device A1. The lead 4 is disposed between the lead 2 and the lead 3.

The support 1 supports the semiconductor element 6 and has a first main surface 11, a first back surface 12, a back surface recess 13, a plurality of terminal back surfaces 18, a plurality of terminal end surfaces 14, and a plurality of connecting end surfaces 15.

The first main surface 11 and the first back surface 12 face opposite each other in the thickness direction z. The first main surface 11 faces the second side 22 in the thickness direction z. The first main surface 11 is a surface on which the semiconductor element 6 is mounted. In the present embodiment, the first main surface 11 has a rectangular shape elongated in the first direction x, with protruding portions on the second side y2 in the second direction y and on the respective sides of the first direction x. There are four protruding portions on the second side y2 in the second direction y, arranged at equal intervals in the first direction x, each of which reaches at the edge on the second side y2 in the second direction y of the semiconductor device A1. There are two protruding portions on the first side x1 in the first direction x, arranged side-by-side in the second direction y, each of which reaches at the edge on the first side x1 in the first direction x of the semiconductor device A1. There are two protruding portions on the second side x2 in the first direction x, arranged side-by-side in the second direction y, each of which reaches at the edge on the second side x2 in the first direction x of the semiconductor device A1. The first back surface 12 faces the first side z1 in the thickness direction z. The first back surface 12 is exposed from the sealing resin 8. In the present embodiment, the first back surface 12 has a rectangular shape elongated in the first direction x.

The back surface recess 13 is a part of the support 1 recessed from the first back surface 12 toward the first main surface 11, and is arranged so as to surround the first back surface 12. The thickness (dimension in the thickness direction z) of the part of the support 1 provided with the back surface recess 13 is about half that of the part of the first back surface 12. The back surface recess 13 may be formed, for example, by half-etching. As shown in FIG. 5, the back surface recess 13 is not exposed from the sealing resin 8, but is covered with the scaling resin 8. This configuration helps to suppress peeling of the support 1 from the sealing resin 8 on the first side z1 in the thickness direction z.

The terminal back surfaces 18 are disposed on the second side y2 in the second direction y of the first back surface 12. The terminal back surfaces 18 face the first side z1 in the thickness direction z, and are exposed from the sealing resin 8. The terminal back surfaces 18 are aligned with the first back surface 12 in the thickness direction z, and are spaced apart from the first back surface 12 with the sealing resin 8 interposed therebetween. The terminal back surfaces 18, as with the first back surface 12, are portions that remain unetched when the back surface recess 13 is formed by half-etching. In the present embodiment, there are four terminal back surfaces 18, arranged at equal intervals in the first direction x, and each of them reaches at the edge on the second side y2 in the second direction y of the semiconductor device A1.

Each terminal end surface 14 is orthogonal to the first main surface 11 and the first back surface 12, and faces the second side y2 of the second direction y. Each terminal end surface 14 is connected to one of the protruding portions on the second side y2 in the second direction y of the first main surface 11 and one of the terminal back surfaces 18. Each terminal end surface 14 is exposed from the sealing resin 8. Each terminal end surface 14 is formed by dicing in a cutting step during the manufacturing process. In the present embodiment, there are four terminal end surfaces 14 that are arranged at equal intervals in the first direction x and are separated by the scaling resin 8. Each terminal end surface 14 and the corresponding terminal back surface 18 connected to it are served as terminals exposed from the sealing resin 8 (see FIGS. 5 and 7).

Each connection end surface 15 is orthogonal to the first main surface 11 and the first back surface 12, and faces the first direction x. Each connecting end surface 15 is connected to the first main surface 11 and the back surface recess 13, and is exposed from the sealing resin 8. Each connection end surface 15 is formed by dicing in a cutting step during the manufacturing process. In the present embodiment, the connection end surfaces 15 include two connection end surfaces 15 facing the first side x1 in the first direction x, and two connection end surfaces 15 facing the second side x2 in the second direction x. The two connecting end surfaces 15 facing the first side x1 in the first direction x are separated by the scaling resin 8, and are aligned in the second direction y. The two connection end surfaces 15 facing the second side x2 in the first direction x are separated by the scaling resin 8, and are aligned in the second direction y.

The shape of the support 1 is not limited to the configuration described above. The support 1 may, for example, have no terminal end surfaces 14 or terminal back surfaces 18. The terminal back surface 18 may be continuous with the first back surface 12. The support 1 may also be configured without the back surface recess 13.

The support 1 has a base member 10 and a metal layer 19. The base member 10 may contain metal, resin, and the like. In the present embodiment, the base member 10 contains a metal, preferably Cu, Ni, alloys thereof or 42 Alloy. Such a support 1 may be referred to as a lead, for example. The base member 10 constitutes the main surface 11, the first back surface 12, the back surface recess 13, the terminal end surfaces 14, and the connecting end surfaces 15.

The metal layer 19 is located on the first main surface 11. The material of the metal layer 19 has a stronger sintered bonding with the sintered metal portion 501 of the bonding material 5 described below than the base member 10. The metal layer 19 may contain, for example, Ag, Au, or Pd. The metal layer 19 may be formed by a plating, for example.

The size and shape of the metal layer 19 is not particularly limited. The metal layer 19 at least partially overlaps with the semiconductor element 6 as viewed in the thickness direction z. In the example shown in FIG. 4, the entire metal layer 19 overlaps with the semiconductor element 6 as viewed in the thickness direction z. In the illustrated example, the center of the semiconductor element 6 overlaps with the metal layer 19. The four corners of the semiconductor element 6 may or may not overlap with the metal layer 19 as viewed in the thickness direction z. In the illustrated example, the metal layer 19 is rectangular as viewed in the thickness direction z. The area of the metal layer 19 may be, for example, not less than 70% and not more than 80% of the area of the semiconductor element 6.

The lead 2 has a second main surface 21, a second back surface 22, a recess 23 in the back side, a plurality of terminal end surfaces 24, and a connecting end surface 25.

The second main surface 21 and the second back surface 22 face opposite each other in the thickness direction z. The second main surface 21 faces the second side 22 in the thickness direction z. The second main surface 21 is a surface to which the wires 71 are bonded. In the present embodiment, the second main surface 21 has a rectangular shape elongated in the first direction x, with protruding portions on the first side y1 in the second direction y. There are two protruding portions, arranged at equal intervals in the first direction x, each of which reaches at the edge on the first side y1 in the second direction y of the semiconductor device A1. The second back surface 22 faces the first side z1 in the thickness direction z. The second back surface 22 is exposed from the sealing resin 8, and is served as a back surface terminal. In the present embodiment, the second back surface 22 has a U-shape that opens on the first side y1 in the second direction y. Both ends of the U-shape reach the edge on the first side y1 in the second direction y of the semiconductor device A1.

The back surface recess 23 is a part of the lead 2 recessed from the second back surface 22 toward the second main surface 21, and is disposed around the second back surface 22. The thickness (dimension in the thickness direction z) of the part of lead 2 provided with the back surface recess 23 is about half that of the part of the second back surface 22. The back surface recess 23 may be formed, for example, by half-etching. As shown in FIG. 5, the back surface recess 23 is not exposed from the sealing resin 8, but is covered with the sealing resin 8. This configuration helps to suppress peeling of the lead 2 from the sealing resin 8 on the first side z1 in the thickness direction z.

Each terminal end surface 24 is orthogonal to the second main surface 21 and the second back surface 22, and faces the first side y1 of the second direction y. Each terminal end surface 24 is connected to one of the protruding portions of the second main surface 21, and one end of the U-shape of the second back surface 22. Each terminal end surface 24 is exposed from the sealing resin 8. Each terminal end surface 24 is formed by dicing in a cutting step during the manufacturing process. In the present embodiment, there are two terminal end surfaces 24 that are arranged in the first direction x and are separated by the sealing resin 8. Each terminal end surface 24 and the second back surface 22 connected to it are served as a terminal exposed from the sealing resin 8 (see FIGS. 2, 5, and 7).

The connection end surface 25 is orthogonal to the second main surface 21 and the second back surface 22, and faces the first side x1 in the first direction x. The connecting end surface 25 is connected to the second main surface 21 and the back surface recess 23, and is exposed from the sealing resin 8. The connection end surface 25 is formed by dicing in a cutting step during the manufacturing process.

The shape of the lead 2 is not limited to the configuration described above. For example, the lead 2 may not have the back surface recess 23.

The lead 3 has a third main surface 31, a third back surface 32, a back surface recess 33, a terminal end surface 34, and a connecting end surface 35.

The third main surface 31 and the third back surface 32 face opposite each other in the thickness direction z. The third main surface 31 faces the second side 22 in the thickness direction z. The third main surface 31 is a surface to which the wire 73 is bonded. In the present embodiment, the third main surface 31 has a rectangular shape elongated in the first direction x, with a protruding portion on the first side y1 in the second direction y. The protruding portion reaches at the edge on the first side y1 in the second direction y of the semiconductor device A1. The third back surface 32 faces the first side z1 in the thickness direction z. The third back surface 32 is exposed from the sealing resin 8, and is served as a back surface terminal. In the present embodiment, the third back surface 32 has a rectangular shape. The third back surface 32 reaches at the edge on the first side y1 in the second direction y of the semiconductor device A1.

The back surface recess 33 is a part of the lead 3 recessed from the third back surface 32 toward the third main surface 31, and is disposed around the third back surface 32. The thickness (dimension in the thickness direction z) of the part of the lead 3 provided with the back surface recess 33 is about half that of the part of the third back surface 32. The back surface recess 33 may be formed, for example, by half-etching. As shown in FIG. 5, the back surface recess 33 is not exposed from the sealing resin 8, but is covered with the sealing resin 8. This configuration helps to suppress peeling of the lead 3 from the sealing resin 8 on the first side z1 in the thickness direction z.

The terminal end surface 34 is orthogonal to the third main surface 31 and the third back surface 32, and faces the first side y1 of the second direction y. The terminal end surface 34 is connected to the protruding portion of the third main surface 31 and the second back surface 22. The terminal end surface 34 is exposed from the sealing resin 8. The terminal end surface 34 is formed by dicing in a cutting step during the manufacturing process. The terminal end surface 34 and the third back surface 32 are served as a terminal exposed from the sealing resin 8 (see FIGS. 2 and 5).

The connection end surface 35 is orthogonal to the third main surface 31 and the third back surface 32, and faces the second side x2 in the first direction x. The connection end surface 35 is connected to the third main surface 31 and the back surface recess 33, and is exposed from the scaling resin 8. The connection end surface 35 is formed by dicing in a cutting step during the manufacturing process.

The shape of the lead 3 is not limited to the configuration described above. For example, the lead 3 may not have the back surface recess 33.

The lead 4 has a fourth main surface 41, a fourth back surface 42, a back surface recess 43, and a terminal end surface 44.

The fourth main surface 41 and the fourth back surface 42 face opposite each other in the thickness direction z. The fourth main surface 41 faces the second side z2 in the thickness direction z. The fourth main surface 41 is a surface to which the wire 72 is bonded. In the present embodiment, the fourth main surface 41 has a rectangular shape, with a protruding portion on the first side y1 in the second direction y. The protruding portion reaches at the edge on the first side y1 in the second direction y of the semiconductor device A1. The fourth back surface 42 faces the first side z1 in the thickness direction z. The fourth back surface 42 is exposed from the sealing resin 8, and is served as a back surface terminal. In the present embodiment, the fourth back surface 42 has a rectangular shape. The fourth back surface 42 reaches at the edge of the semiconductor device A1 on the first side y1 in the second direction y.

The back surface recess 43 is a part of the lead 4 recessed from the fourth back surface 42 toward the fourth main surface 41, and is disposed around the fourth back surface 42. The thickness (dimension in the thickness direction z) of the part of lead 4 provided with the back surface recess 43 is about half that of the part of the fourth back surface 42. The back surface recess 43 may be formed, for example, by half-etching. As shown in FIG. 5, the back surface recess 43 is not exposed from the sealing resin 8, but is covered with the sealing resin 8. This configuration helps to suppress peeling of the lead 4 from the sealing resin 8 on the first side z1 in the thickness direction z.

The terminal end surface 44 is orthogonal to the fourth main surface 41 and the fourth back surface 42, and faces the first side y1 of the second direction y. The terminal end surface 44 is connected to the protruding portion of the fourth main surface 41 and the fourth back surface 42. The terminal end surface 44 is exposed from the sealing resin 8. The terminal end surface 44 is formed by dicing in a cutting step during the manufacturing process. The terminal end surface 44 and the fourth back surface 42 are served as a terminal exposed from the sealing resin 8 (see FIGS. 2 and 5).

The shape of the lead 4 is not limited to the configuration described above. For example, the lead 4 may not have the back surface recess 43.

The semiconductor element 6 performs an electrical function of the semiconductor device A1. The type of semiconductor element 6 is not particularly limited. In the present embodiment, the semiconductor element 6 may be a metal-oxide-semiconductor field-effect transistor (MOSFET). The semiconductor element 6 may alternatively be other switching element such as an Insulated Gate Bipolar Transistor (IGBT), or a High Electron Mobility Transistor (HEMT). The semiconductor element 6 may include an element body 60, a first electrode 61, a second electrode 62, and a third electrode 63.

The element body 60 is a plate with a rectangular shape as viewed in the thickness direction z. The element body 60 contains a semiconductor material 1, and in the present embodiment, includes silicon (Si). The element body 60 may alternatively contain other semiconductor materials, such as silicon carbide (SiC) or gallium nitride (GaN). The element body 60 has an element main surface 6a and an element back surface 6b. The element main surface 6a and the element back surface 6b face opposite each other in the thickness direction z. The element main surface 6a faces the second side 22 in the thickness direction z. The element back surface 6b faces the first side z1 in the thickness direction z. The first electrode 61 and the second electrode 62 are disposed on the element main surface 6a. The third electrode 63 is disposed on the element back surface 6b. In the present embodiment, the first electrode 61 is a source electrode, the second electrode 62 is a gate electrode, and the third electrode 63 is a drain electrode. The third electrode 63 is preferably made of a material suitable for a sintered bonding with the sintered metal portion 501 of the bonding material 5 described below, and may contain, for example, Ag, Au, Pd or the like.

As shown in FIGS. 6 and 7, the semiconductor element 6 is mounted at a central portion of the first main surface 11 of the support 1 via the bonding material 5. The semiconductor element 6 is bonded to the first main surface 11 of the support 1 via the bonding material 5 at its element back surface 6b. In the present embodiment, the third electrode 63 of the semiconductor element 6 is electrically connected to the support 1 via the bonding material 5. Hence, the support 1 is electrically connected to the third electrode 63 (drain electrode) of the semiconductor element 6 and is served as a drain terminal.

As shown in FIG. 9, the bonding material 5 includes a sintered metal portion 501 and a resin portion 502. The sintered metal portion 501 may contain a metal such as Ag, Cu or the like. The sintered metal portion 501 is bonded together by sintering treatment and may have fine gaps therein. The resin portion 502 may be filled into the fine gaps in the sintered metal portion 501. The resin portion 502 may contain, for example, an epoxy resin, an acrylic resin or the like, and may have heat-shrinkable properties.

The bonding material 5 includes a first portion 51 and a second portion 52. The first portion 51 is in contact with the semiconductor element 6 and the metal layer 19. In the illustrated example, the first portion 51 is in contact with the third electrode 63. The second portion 52 is in contact with the semiconductor element 6 and the base member 10. In the illustrated example, the second portion 52 is in contact with the third electrode 63. In FIG. 4, for convenience of understanding, the metal layer 19 is illustrated with a hidden line (dotted line), the first portion 51 is hatched with a plurality of discrete dots, and the second portion 52 is hatched with a plurality of diagonal lines.

In the first portion 51, the sintered metal portion 501 is bonded to the third electrode 63 by sintered bonding. The sintered metal portion 501 is bonded to the metal layer 19 by sintered bonding. Hence, the third electrode 63 and the metal layer 19 are bonded via the sintered metal portion 501 of the bonding material 5, and are conductively bonded in the illustrated example. In the first portion 51, the bonding strength provided by the sintered metal portion 501 to the third electrode 63 and the metal layer 19 may be stronger and dominant compared to the contribution from the resin portion 502. If the semiconductor element 6 has, instead of the third electrode 63, a metal layer (not shown) that does not serve an electrical function, the semiconductor element 6 may be configured not to be electrically connected to the support 1.

In the second portion 52, the sintered bonding strength between the sintered metal portion 501 and the base member 10 is weaker than the sintered bonding strength between the sintered metal portion 501 and the metal layer 19. Thus, the bonding strength of the resin portion 502 and the base member 10 may be stronger and dominant compared to the bonding strength of the sintered metal portion 501 and the base member 10.

As viewed in the thickness direction z, the bonding material 5 may extend beyond or entirely overlap with the semiconductor element 6.

As shown in FIG. 3, the second electrode 62 of the semiconductor element 6 is electrically connected to the lead 3 via the wire 73. Hence, the lead 3 is electrically connected to the second electrode 62 (gate electrode) of the semiconductor element 6, and is served as a gate terminal. As shown in FIG. 3, the first electrode 61 of the semiconductor element 6 is electrically connected to the lead 2 via the wires 71. Hence, the lead 2 is electrically connected to the first electrode 61 (source electrode) of the semiconductor element 6, and is served as a source terminal. Furthermore, as shown in FIG. 3, the first electrode 61 of the semiconductor element 6 is also electrically connected to the lead 4 via the wire 72. Hence, the lead 4 is electrically connected to the first electrode 61 (source electrode) of the semiconductor element 6, and is served as a sense source terminal. The sense source terminal detects the potential of the first electrode 61 (source electrode).

The wires 71 to 73 connect the semiconductor element 6 to the leads 2, 3, and 4, thereby electrically connecting them. The wires 71 to 73 may contain metals such as Cu, Au, Ag, A1, or the like. The material of wires 71 to 73 is not limited. As shown in FIG. 3, the wires 71 are each bonded to the first electrode 61 of the semiconductor element 6 and the second main surface 21 of the lead 2. In the present embodiment, the first electrode 61 is connected to the support 1 with six wires 71. The number of the wires 71 is not limited thereto. The wire 72 is bonded to the first electrode 61 of the semiconductor element 6 and the fourth main surface 41 of the lead 4. In the present embodiment, the first electrode 61 is connected to the lead 4 with one wire 72. The number of the wires 72 is not limited thereto. The wire 73 is bonded to the second electrode 62 of the semiconductor element 6 and the third main surface 31 of the lead 3. In the present embodiment, the second electrode 62 is connected to the lead 3 with one wire 73. The number of the wires 73 is not limited thereto. Instead of the wires 71 to 74, other conductive members such as those formed from a metal plate material may be applied

The sealing resin 8 covers the support 1, the semiconductor element 6, the bonding material 5, the wires 71 to 73, and a part of the leads 2, 3, and 4. The sealing resin 8 is made of a black epoxy resin, for example. The material of the sealing resin 8 is not limited.

The sealing resin 8 has a resin main surface 81, a resin back surface 82, and four resin side surfaces 83. The resin main surface 81 and the resin back surface 82 face opposite each other in the thickness direction z. The resin main surface 81 faces the second side 22 in the thickness direction z, and the resin back surface 82 faces the first side z1 in the thickness direction z.

Four resin side surfaces 83 are each orthogonal to the resin main surface 81 and the resin back surface 82, connect the resin main surface 81 and the resin back surface 82, and face outward in the first direction x or the second direction y, respectively. Each resin side surface 83 is formed by dicing in a cutting step during the manufacturing process. The four resin sides 83 include a resin side surface 831, a resin side surface 832, a resin side surface 833, and a resin side surface 834. The resin side surfaces 831 and 832 face opposite each other in the first direction x. The resin side surface 831 is disposed on the first side x1 in the first direction x, and faces the first side x1 in the first direction x. The resin side surface 832 is disposed on the second side x2 in the first direction x, and faces the second side x2 in the first direction x. The resin side surface 833 and the resin side surface 834 face opposite each other in the second direction y. The resin side surface 833 is disposed on the first side y1 in the second direction y, and faces the first side y1 in the second direction y. The resin side surface 834 is disposed on the second side y2 in the second direction y, and faces the second side y2 in the second direction y.

As shown in FIGS. 2 and 5, the first back surface 12 and the terminal back surfaces 18 of the support lead 1, the second back surface 22 of the lead 2, the third back surface 32 of the lead 3, and the fourth back surface 42 of the lead 4 are exposed from and flush with the resin back surface 82 of the sealing resin 8.

The two connecting end surfaces 15 of the support 1 facing the first side x1 in the first direction x and the connecting end surface 25 of the lead 2 are exposed from and flush with the resin side surface 831. The two connecting end surfaces 15 of the support 1 facing the second side face x2 in the first direction x and the connecting end surface 35 of the lead 3 are exposed from and flush with the resin side surface 832. The terminal end surfaces 24 of the lead 2, the terminal end surface 34 of the lead 3, and the terminal end surface 44 of the lead 4 are exposed from and flush with the resin side surface 833. The terminal end surfaces 14 of the support 1 are exposed from and flush with the resin side surface 834.

Next, the operation of the semiconductor device A1 will be described.

As shown in FIGS. 4 and 6 to 9, the bonding material 5 includes a first portion 51 and a second portion 52. In the first portion 51, the sintered metal portion 501 has relatively strong sintered bonding strength. On the other hand, in the second portion 52, the resin portion 502 has relatively strong sintered bonding strength. Thus, stronger bonding can be achieved by the first portion 51, while flexibility can be imparted by the bonding of the second portion 52. Unlike the present embodiment, if all of the bonding material 5 were configured entirely like the first portion 51, excessive stresses such as thermal stress could occur because of the strong sintered bonding over the entire area of the bonding material 5. Such stress may cause cracking, peeling, or other defects in the bonding material 5. With such a configuration, such excessive stresses can be suppressed by the flexibility provided by the second portion 52. Therefore, it is possible to reduce defects in the bonding material 5.

As viewed in the thickness direction z, the semiconductor element 6 has a rectangular shape whose four corners do not overlap with the metal layer 19. The four corners of the semiconductor element 6 are bonded to the base member 10 via the second portion 52. When the semiconductor element 6 repeatedly generates heat during use of the semiconductor device A1, excessive stresses tend to occur particularly at the parts of the bonding material 5 bonding the four corners of the semiconductor element 6. In the present embodiment, the second portion 52 may deform more flexibly at the four corners of the semiconductor element 6, thereby suppressing the occurrence of excessive stress in the bonding material 5. Therefore, such a configuration is advantageous in reducing defects in the bonding material 5.

The metal layer 19 has a rectangular shape as viewed in the thickness direction z. When the semiconductor element 6 of the illustrated size is mounted on the support 1, the metal layer 19 is smaller than the semiconductor element 6. Consequently, the four corners of the semiconductor element 6 extend beyond the metal layer 19. On the other hand, if the semiconductor element 6 equal to or smaller than the size of the metal layer 19 is mounted on the support 1, the semiconductor element 6 may be bonded to the metal layer 19 via the first portion 51 alone. In cases where the semiconductor element 6 is small, the stresses generated at the four corners of the semiconductor element 6 may be significantly reduced. Thus, even if the semiconductor element 6 is bonded to the metal layer 19 via the first portion 51 alone, defects such as cracking or peeling are less likely to occur, and the entire surface of the third electrode 63 can be conductively bonded to the metal layer 19 through sintered bonding. This is advantageous in reducing resistance and promoting heat transfer between the semiconductor element 6 and the support 1.

The semiconductor element 6 of the present embodiment is a switching element including a MOSFET. Switching elements are required to switch large currents and generate significant heat during conduction. With such a configuration, it is advantageous in allowing conduction of large currents due to reduced resistance, and in enhancing heat dissipation from the semiconductor element 6.

The first back surface 12 of the support body 1 is exposed from the sealing resin 8, thereby enhancing heat dissipation from the semiconductor element 6.

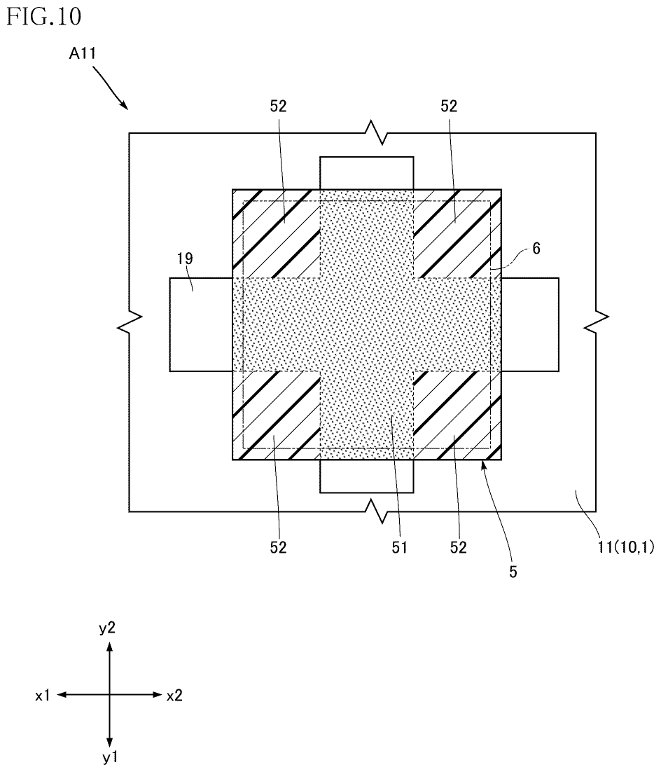

FIGS. 10 to 19 show other embodiments of the present disclosure. In these figures, elements identical or similar to the above embodiment are marked with the same symbols as in the above embodiment. Various parts of embodiments and variations may be selectively used in any appropriate combination as long as it is technically compatible.

FIG. 10 shows a first variation of the semiconductor device A1. A semiconductor device A11 of the present variation differs from the above example in the configuration of the metal layer 19, the first portion 51 and the second portion 52.

In the present variation, the metal layer 19 has a cross shape as viewed in the thickness direction z. The metal layer 19 includes a portion extending along the first direction x and a portion extending along the second direction y. The metal layer 19 may overlap with a central portion of the semiconductor element 6 as viewed in the thickness direction z. The four corners of the semiconductor element 6 do not overlap with the metal layer 19 as viewed in the thickness direction z. As viewed in the thickness direction z, the metal layer 19 extends beyond the semiconductor element 6 in the first direction x and the second direction y.

The first portion 51 has a cross shape corresponding to the shape of the metal layer 19 as viewed in the thickness direction z. The first portion 51 includes a portion extending along the first direction x and a portion extending along the second direction y. The bonding material 5 of the present variation includes a plurality of second portions 52. Specifically, the bonding material 5 includes four second portions 52, which are divided from each other by the first portion 51. The four second portions 52 overlap with the respective four corners of the semiconductor element 6.

The present variation is advantageous in reducing defects in the bonding material 5. As understood from the present variation, the shape and size of the metal layer 19 is not particularly limited. In cases where the metal layer 19 is formed in a cross shape, it is possible to prevent the four corners of the semiconductor element 6 from overlapping with the metal layer 19 while also allowing the size of the first portion 51 to be enlarged. This is advantageous for enhancing the bonding strength between the semiconductor element 6 and the support 1.

Since the metal layer 19 extends beyond the semiconductor element 6, it is possible to accommodate a larger semiconductor element than the semiconductor element 6 illustrated in FIG. 10, while still maintaining a configuration in which the bonding material 5 includes the first portion 51 and the four second portions 52. Thus, it is possible to accommodate a greater variety of sizes of semiconductor elements 6.

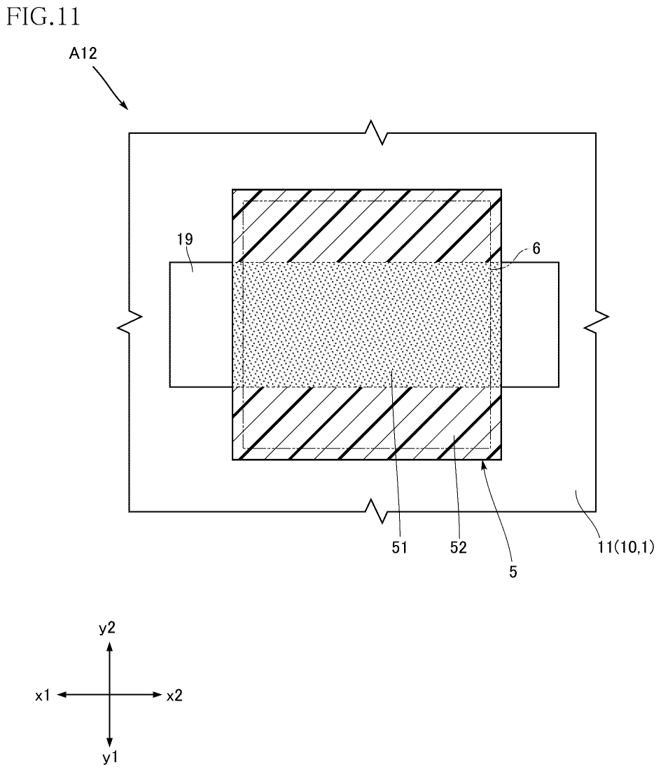

FIG. 11 shows a second variation of the semiconductor device A1. A semiconductor device A12 of the present variation includes the metal layer 19 having a band shape extending in the first direction x. The metal layer 19 does not extend beyond the semiconductor element 6 in the second direction y. The metal layer 19 may overlap with the center of the semiconductor element 6, while not overlapping with the four corners of the semiconductor element 6.

The present variation is advantageous in reducing defects in the bonding material 5. The present variation can also achieve the effect of avoiding the four corners of the semiconductor element 6 overlapping with the metal layer 19.

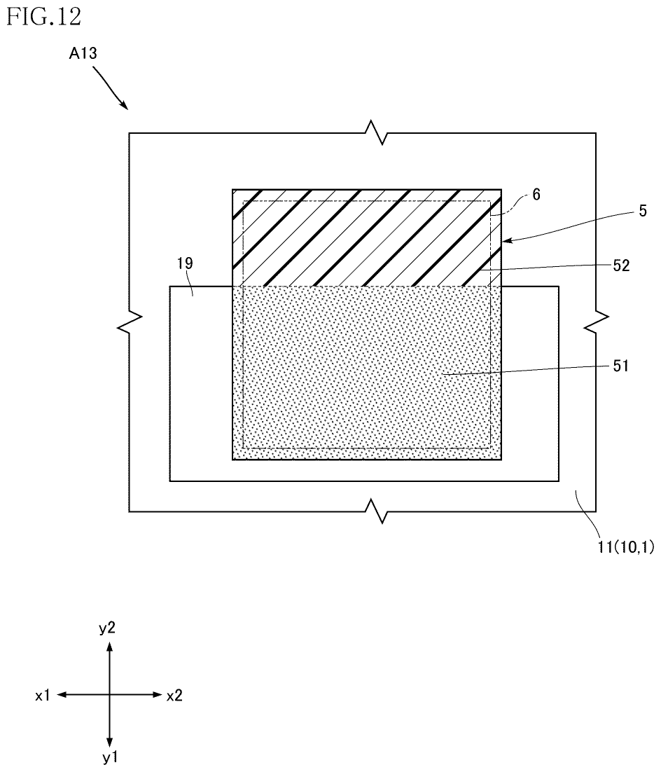

FIG. 12 shows a third variation of the semiconductor device A1. A semiconductor device A13 of the present variation includes the metal layer 19 having a band shape extending in the first direction x. The metal layer 19 overlaps with two of the four corners of the semiconductor element 6 on the first side y1 in the second direction y, and does not overlap with the other two corners on the second side y2 in the second direction y. The metal layer 19 may be configured to overlap, or not to overlap, with the center of the semiconductor element 6.

The present variation is advantageous in reducing defects in the bonding material 5.

Depending on the shape, and internal structure, and heat generation pattern of the semiconductor element 6, or the configuration of the conductive members including the wires 71, thermal deformation of the semiconductor element 6 may become asymmetrical as viewed in the thickness direction z. In such a case, defects in the bonding material 5 can be reduced by bonding two of the four corners of the semiconductor element 6, which are expected to experience relatively less thermal deformation, with the first portion 51, and bonding the other two corners with the second portion 52.

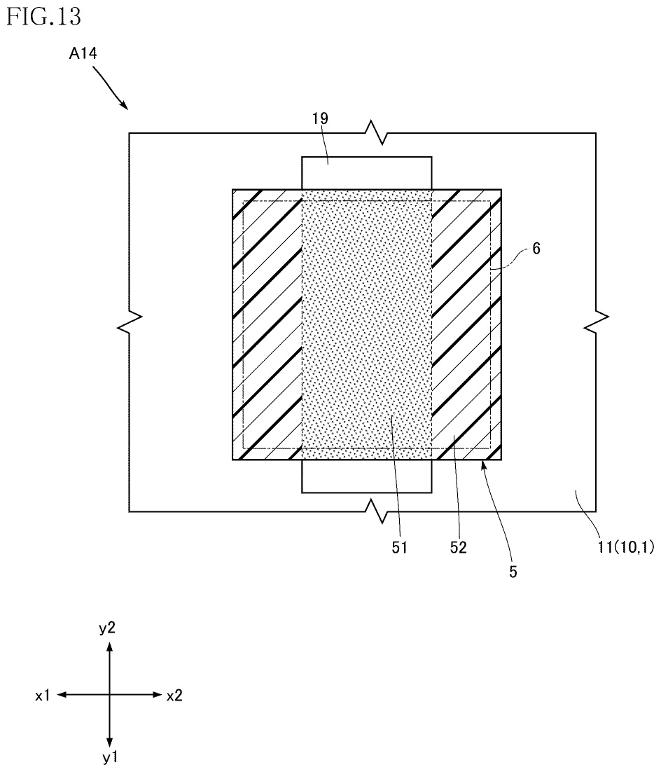

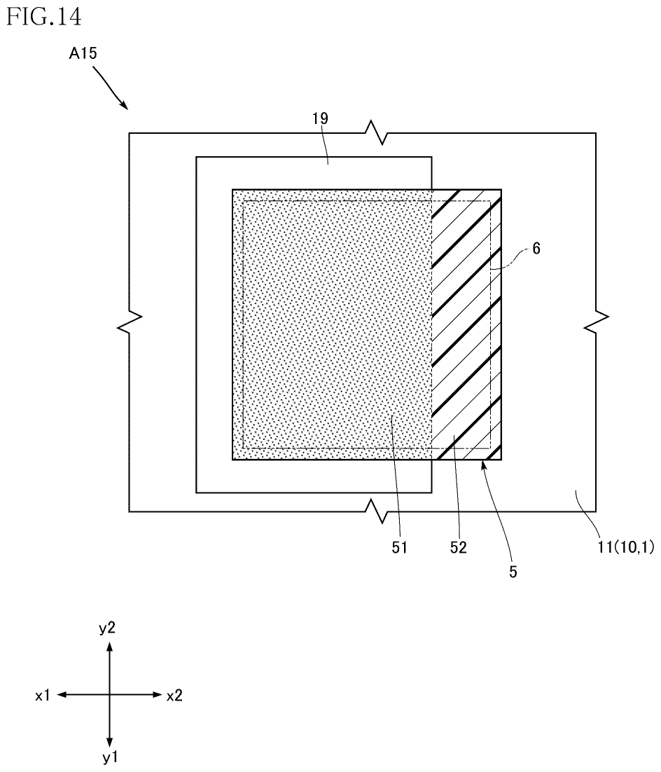

FIG. 13 shows a fourth variation of the semiconductor device A1. A semiconductor device A14 of the present variation includes the metal layer 19 with a band shape extending in the second direction y and not overlapping with the four corners of the semiconductor element 6. FIG. 14 shows a fifth variation of the semiconductor device A1. A semiconductor device A15 of the present variation includes the metal layer 19 overlapping with two of the four corners of the semiconductor element 6 on the first side x1 in the first direction x and not overlapping with two of the four corners on the second side x2. Such a configuration may achieve the same effect as in the semiconductor devices A12 and A13. Additionally, when the metal layer 19 has a band shape, the extending direction of the metal layer 19 is not particularly limited, and may be the first direction x, the second direction y, or in directions inclined with respect to the first direction x and the second direction y.

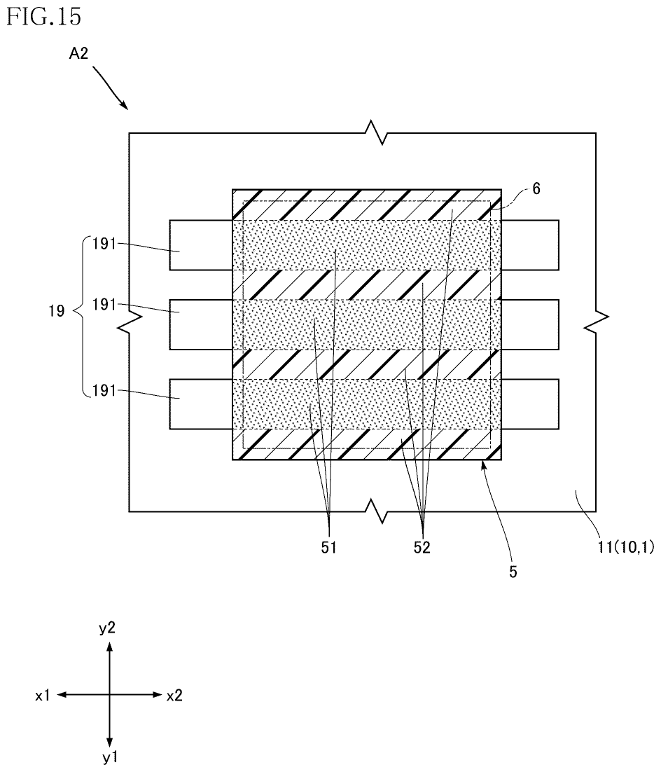

FIG. 15 shows a semiconductor device according to a second embodiment of the present disclosure. In the semiconductor device A2, the metal layer 19 includes a plurality of separate regions 191.

The separate regions 191 are spaced apart from each other as viewed in the thickness direction z. The number, shape, size and relative positional arrangement of the separate regions 191 are not particularly limited. In the illustrated example, each separated region 191 is formed in a band shape extending along the first direction x. The separated regions 191 are arranged in the second direction y. The separate regions 191 may not overlap with the four corners of the semiconductor element 6. At least one of the separate regions 191 may overlap with the center of the semiconductor element 6.

Corresponding to the configuration of the metal layer 19, the bonding material 5 includes a plurality of first portions 51 and a plurality of second portions 52. Each of the first portions 51 and the second portions 52 has a band shape extending in the first direction x.

The present embodiment is advantageous in reducing defects in the bonding material 5. In addition, the metal layer 19 includes the separate regions 191, thereby reducing stress that can occur in the first portions 51.

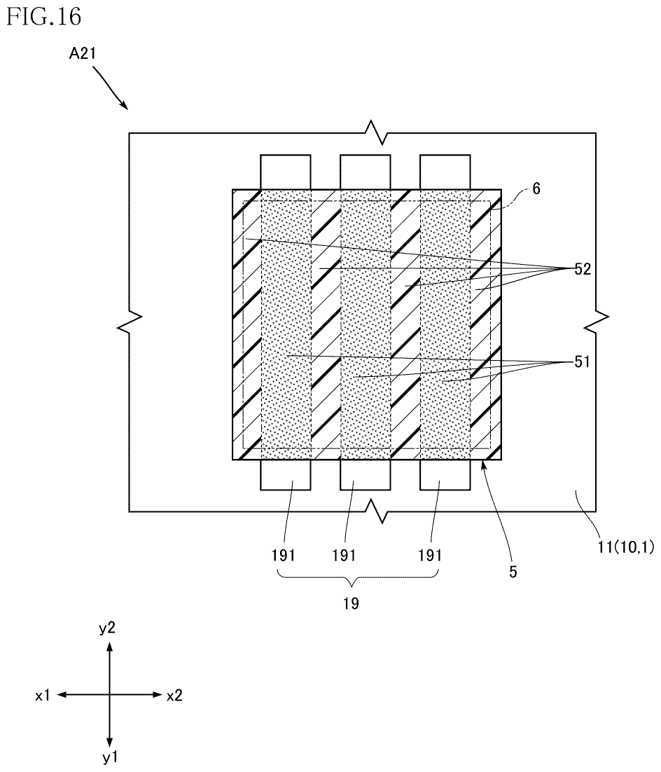

FIG. 16 shows a first variation of the semiconductor device A2. A semiconductor device A21 of the present variation includes the separated regions 191 each extending in the second direction y. The present variation may achieve the same effect as in the semiconductor device A2. As understood from the present variation, when each of the separated regions 191 has a band shape, the extending direction of each separated region 191 is not particularly limited and may be the first direction x, the second direction y, or a direction inclined with respect to the first direction x and the second direction y.

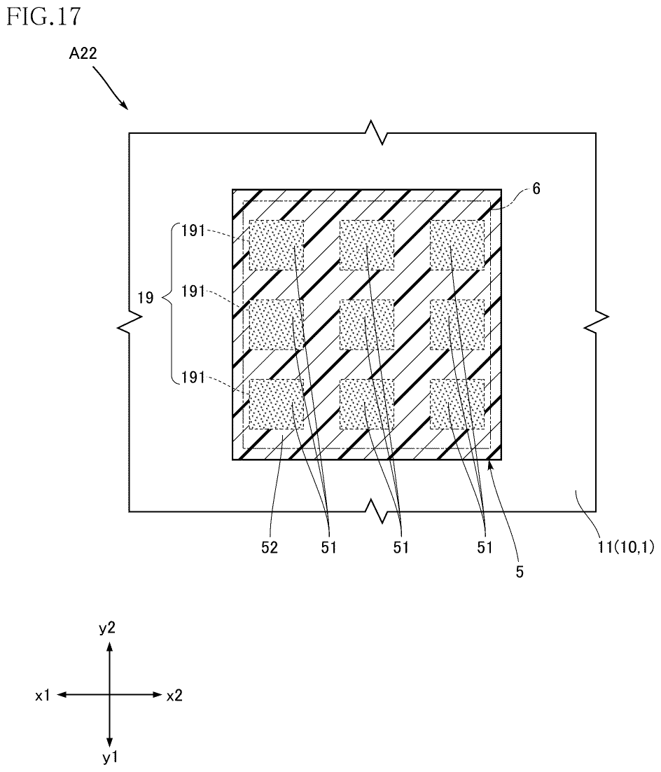

FIG. 17 shows a second variation of the semiconductor device A2. A semiconductor device A22 of the present variation includes the separate regions 191 arranged in a matrix pattern.

The separated regions 191 are spaced apart from each other in the first direction x and the second direction y. In the illustrated example, the separated regions 191 are arranged in a matrix pattern along the first direction x and the second direction y.

The present variation is advantageous in reducing defects in the bonding material 5. The separated regions 191 are arranged two-dimensionally apart from each other, thereby reducing stresses that may occur in the first portion 51. The two-dimensional arrangement of the separate regions 191 is not limited to the illustrated example. It may be a staggered arrangement or even an irregular arrangement.

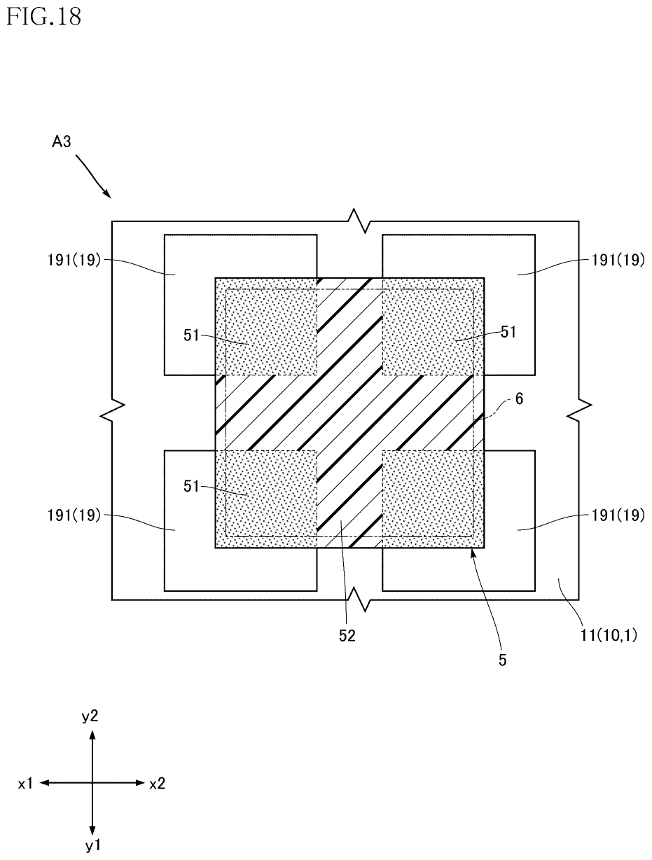

FIG. 18 shows a semiconductor device according to a third embodiment of the present disclosure. A semiconductor device A3 of the present embodiment includes the metal layer 19 including the separate regions 191. In the illustrated example, the metal layer 19 includes four separate regions 191. The four separate regions 191 overlap with the respective four corners of the semiconductor element 6.

In the present embodiment, the bonding material 5 includes multiple first portions 51 and one second portion 52 corresponding to the configuration of the metal layer 19. The second portion 52 has a cross shape as viewed in the thickness direction z and defines the first portions 51. The first portions 51 bonds the respective four corners of the semiconductor element 6 to the metal layer 19.

The present embodiment is advantageous in reducing defects in the bonding material 5. The separate regions 191 overlap with the respective four corners of the semiconductor element 6, thereby bonding more firmly the four corners of the semiconductor element 6 to the metal layer 19 (support 1). In addition, the separated regions 191 are spaced apart from each other, so that the multiple first portions 51 can move independently. This allows the four corners of the semiconductor element 6 to be bonded more firmly while reducing stresses that may occur in the bonding material 5 (first portion 51).

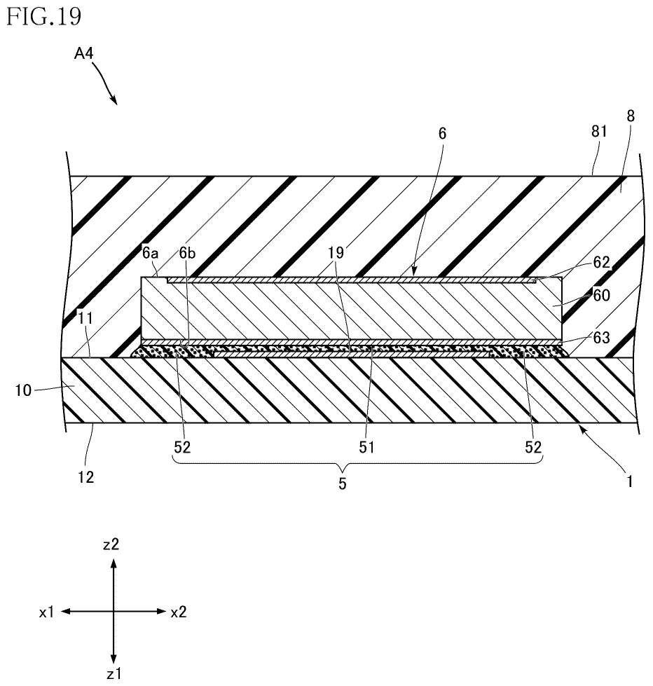

FIG. 19 shows a semiconductor device according to a fourth embodiment of the present disclosure. A semiconductor device A4 of the present embodiment includes the base member 10 containing a resin. An example of such a support 1 may be a printed circuit board. The base member 10 may contain, for example, a glass epoxy resin.

The present embodiment is advantageous in reducing defects in the bonding material 5. As understood from the present embodiment, various materials such as metal, resin or the like may be selectively adopted for the base member 10.

The semiconductor devices according to the present disclosure are not limited to the embodiments described above. The specific configuration of each part of the semiconductor device of the present disclosure may suitably be designed and changed in various manners. The present disclosure includes the embodiments described in the following clauses.

### Clause 1.

A semiconductor device (A1) comprising:
a support (1) including a base member (10) having a first main surface (11) facing a thickness direction (z);
a semiconductor element (6); and
a bonding material (5) that bonds the support (1) and the semiconductor element (6),
wherein the bonding material (5) includes a sintered metal portion (501) and a resin portion (502),
the support (1) includes a metal layer (19) located on the first main surface (11) and having a stronger sintered bonding with the sintered metal portion (501) than the base member (10), and
the bonding material (5) includes a first portion (51) in contact with the semiconductor element (6) and the metal layer (19), and a second portion (52) in contact with the semiconductor element (6) and the base member (10).

### Clause 2.

The semiconductor device (A1) according to clause 1, wherein the semiconductor element (6) is conductively bonded to the support (1).

### Clause 2-1.

The semiconductor device (A1) according to clause 2, wherein the semiconductor element (6) includes a third electrode (63) conductively bonded to the support (1) via the bonding material (5)

### Clause 3.

The semiconductor device (A1) according to clause 1 or 2, wherein the metal layer (19) overlaps with only a part of the semiconductor element (6) as viewed in the thickness direction (z).

### Clause 4.

The semiconductor device (A1) according to clause 3, wherein the semiconductor element (6) has a rectangular shape as viewed in the thickness direction (z), and four corners of the semiconductor element (6) do not overlap with the metal layer (19) as viewed in the thickness direction (z).

### Clause 4-1.

The semiconductor device (A1) according to clause 4, wherein the metal layer (19) overlaps with a central portion of the semiconductor element (6) as viewed in the thickness direction (z).

### Clause 5.

The semiconductor device (A1) according to clause 4, wherein the metal layer (19) has a cross shape as viewed in the thickness direction (z).

### Clause 6.

The semiconductor device (A12, A14) according to clause 3 or 4, wherein the metal layer (19) has a band shape extending in a direction intersecting the thickness direction (z), as viewed in the thickness direction (z).

### Clause 7.

The semiconductor device (A13, A15) according to clause 6, wherein the metal layer (19) overlaps with two of four corners of the semiconductor element (6) and does not overlap with the other two as viewed in the thickness direction (z).

### Clause 8.

The semiconductor device (A2) according to any one of clauses 1 to 7, wherein the metal layer (19) includes a plurality of separate regions (191) spaced apart from each other as viewed in the thickness direction (z).

### Clause 9.

The semiconductor device (A2, A21) according to clause 8, wherein each of the plurality of separate regions (191) has a band shape extending in a direction intersecting the thickness direction (z).

### Clause 10.

The semiconductor device (A2, A22) according to clause 8, wherein the plurality of separate regions (191) are arranged in a matrix pattern as viewed in the thickness direction (z).

### Clause 11.

The semiconductor device (A3) according to clause 8, wherein at least one of the plurality of separate regions (191) overlaps with a corner of the semiconductor element (6) as viewed in the thickness direction (z).

### Clause 12.

The semiconductor device (A3) according to clause 11, wherein the plurality of separate regions (191) do not overlap with a central portion of the semiconductor element (6) as viewed in the thickness direction (z).

### Clause 13.

The semiconductor device (A1) according to any one of clauses 1 to 12, wherein the metal layer (19) extends beyond the semiconductor element (6) as viewed in the thickness direction (z).

### Clause 14.

The semiconductor device (A1) according to any one of clauses 1 to 13, wherein the base member (10) contains a metal.

### Clause 14-1.

The semiconductor device (A1) according to clause 14, wherein the base member (10) contains a copper.

### Clause 15.

The semiconductor device (A1) according to any one of clauses 1 to 13, wherein the base member (10) contains a resin.

### Clause 16.

The semiconductor device (A1) according to any one of clauses 1 to 15, wherein the sintered metal portion (501) contains a silver or a copper.

### Clause 17.

The semiconductor device (A1) according to any one of clauses 1 to 16, wherein the resin portion (502) contains an epoxy resin or an acrylic resin.

### Clause 18.

The semiconductor device (A1) according to any one of clauses 1 to 17, further comprising a sealing resin (8) covering the semiconductor element (6).

### Clause 19.

The semiconductor device (A1) according to clause 18, wherein the support (1) has a first back surface (12) facing opposite to the first main surface (11), and the first back surface (12) is exposed from the sealing resin (8).

### Clause 20.

The semiconductor device (A1) according to any one of clauses 1 to 19, wherein the semiconductor element (6) is a switching element.

### REFERENCE NUMERALS

A1, A11, A12, A13, A14, A15, A2, A21, A22, A3, A4: Semiconductor device
1: Support 2, 3, 4: Lead 5: Bonding material
6: Semiconductor element 6a: Element main surface
6b: Element back surface 8: Sealing resin
10: Base member 11: First main surface 12: First back surface
13, 23, 33, 43: Back surface recess 14, 24, 34, 44: Terminal end surface
15, 25, 35: Connection end surface 18: Terminal back surface
19: Metal layer 21: Second main surface 22: Second back surface
31: Third main surface 32: Third back surface
41: Fourth main surface 42: Fourth back surface
51: First portion 52: Second portion 60: Element body
61: First electrode 62: Second electrode 63: Third electrode
71, 72, 73, 74: Wire 81: Resin main surface 82: Resin back surface
83: Resin side surface 191: Separated region
501: Sintered metal portion 502: Resin portion
831, 832, 833, 834: Resin side surface
x: First direction y: Second direction z: Thickness direction

1. A semiconductor device comprising:
a support including a base member having a first main surface facing a thickness direction;
a semiconductor element; and
a bonding material that bonds the support and the semiconductor element,
wherein the bonding material includes a sintered metal portion and a resin portion,
the support includes a metal layer located on the first main surface and having a stronger sintered bonding with the sintered metal portion than the base member, and
the bonding material includes a first portion in contact with the semiconductor element and the metal layer, and a second portion in contact with the semiconductor element and the base member.

2. The semiconductor device according to claim 1, wherein the semiconductor element is conductively bonded to the support.

3. The semiconductor device according to claim 1, wherein the metal layer overlaps with only a part of the semiconductor element as viewed in the thickness direction.

4. The semiconductor device according to claim 3, wherein the semiconductor element has a rectangular shape as viewed in the thickness direction, and
four corners of the semiconductor element do not overlap with the metal layer as viewed in the thickness direction.

5. The semiconductor device according to claim 4, wherein the metal layer has a cross shape as viewed in the thickness direction.

6. The semiconductor device according to claim 3, wherein the metal layer has a band shape extending in a direction intersecting the thickness direction, as viewed in the thickness direction.

7. The semiconductor device according to claim 6, wherein the metal layer overlaps with two of four corners of the semiconductor element and does not overlap with the other two as viewed in the thickness direction.

8. The semiconductor device according to claim 1, wherein the metal layer includes a plurality of separate regions spaced apart from each other as viewed in the thickness direction.

9. The semiconductor device according to claim 8, wherein each of the plurality of separate regions has a band shape extending in a direction intersecting the thickness direction.

10. The semiconductor device according to claim 8, wherein the plurality of separate regions are arranged in a matrix pattern as viewed in the thickness direction.

11. The semiconductor device according to claim 8, wherein at least one of the plurality of separate regions overlaps with a corner of the semiconductor element as viewed in the thickness direction.

12. The semiconductor device according to claim 11, wherein the plurality of separate regions do not overlap with a central portion of the semiconductor element as viewed in the thickness direction.

13. The semiconductor device according to claim 1, wherein the metal layer extends beyond the semiconductor element as viewed in the thickness direction.

14. The semiconductor device according to claim 1, wherein the base member contains a metal.

15. The semiconductor device according to claim 1, wherein the base member contains a resin.
